(19) United States
(12) Patent Application Publication
(10) Pub. No.: US 2015/0101754 A1
(43) Pub. Date: Apr. 16, 2015

(54) APPARATUS FOR TREATING SUBSTRATE AND METHOD FOR CARRYING SUBSTRATE

(71) Applicant: PSK INC., Gyeonggi-do (KR)

(72) Inventor: Seung Kook YANG, Hwaseong-si (KR)

(21) Appl. No.: 14/504,988

(22) Filed: Oct. 2, 2014

(30) Foreign Application Priority Data
Oct. 10, 2013 (KR) 10-2013-0120792

(51) Int. Cl. H01L 21/677; H01L 21/687

(52) U.S. Cl. CPC H01L 21/67703; H01L 21/67742; H01L 21/67745; H01L 21/67748; H01L 21/68714
USPC 156/345.31; 414/222.08; 414/806

(57) ABSTRACT

Provided is an apparatus for treating a substrate. The apparatus for treating the substrate includes a carrying unit between a second chamber and a loadlock chamber. The carrying unit includes an arm, a blade for supporting the substrate, and a rotation driver for rotating the arm. The carrying unit disposed between the second chamber and the loadlock chamber receives the substrate transferred in the loadlock chamber to transfer the substrate onto a substrate supporter in the second chamber.

### CROSS-REFERENCE TO RELATED APPLICATIONS

This U.S. non-provisional patent application claims priority under 35 U.S.C. § 119 of Korean Patent Application No. 10-2013-0120792, filed on Oct. 10, 2013, the entire contents of which are hereby incorporated by reference.

### BACKGROUND OF THE INVENTION

The present invention disclosed herein relates to an apparatus for treating a substrate and a method for carrying the substrate.

In general, a process for treating a substrate such as a semiconductor wafer or a glass substrate includes a plasma treatment processes such as etching, ashing, and deposition and a cleaning process for cleaning a surface of the substrate. In general, the plasma treating process is performed under the vacuum condition, and the cleaning process is performed at an atmospheric pressure.

Thus, devices for performing the processes are separately provided, and the substrate is transferred between the plasma treating device and the cleaning device.

### SUMMARY OF THE INVENTION

The present invention provides a substrate treatment apparatus and a substrate carrying method that are capable of performing both an atmospheric pressure process and a vacuum process when a substrate treatment process is performed.

The present invention also provides a substrate treatment apparatus and a substrate carrying method reduced in foot print.

The feature of the present invention is not limited to the aforesaid, but other features not described herein will be clearly understood by those skilled in the art from descriptions below.

Embodiments of the present invention provide apparatuses for treating a substrate, the apparatuses including: an index module; and a treatment module, wherein the index module includes: a load port on which a container accommodating the substrate is placed; and a frame in which an index robot for carrying the substrate between the container and the treatment module is disposed, and the treatment module includes: process chambers including a first chamber and a second chamber; a loadlock chamber; a transfer chamber in which a main robot for transferring the substrate between the first chamber and the loadlock chamber is disposed; and a carrying unit for carrying the substrate between the second chamber and the loadlock chamber, wherein the carrying unit includes: an arm; a blade disposed on the arm to support the substrate; and a rotation driver for rotating the arm, wherein the first and loadlock chambers are disposed on a side portion of the transfer chamber, the second chamber is disposed between the loadlock chamber and the frame, and a distance between the second chamber and the loadlock chamber is shorter than that of the arm.

In some embodiments, the carrying unit may further include a blade driver for moving the blade along a longitudinal direction of the arm on the arm, and the rotation driver rotates the arm with respect to a central axis of the arm.

In other embodiments, the rotation driver may rotate the arm with respect to one end of the arm, and the blade may be disposed on the other end of the arm.

In other embodiments of the present invention, apparatuses for treating a substrate includes: a first unit; a second unit; a carrying unit disposed between the first unit and the second unit, wherein the carrying unit includes: an arm; a blade disposed on the arm to support a substrate; and a rotation driver for rotating the arm, wherein a distance between the first unit and the second unit is shorter than that of the arm.

In some embodiments, the carrying unit may further include a blade driver for moving the blade along a longitudinal direction of the arm on the arm, the rotation driver rotates the arm with respect to a central axis of the arm.

In other embodiments, the rotation driver may rotate the arm with respect to one end of the arm, and the blade may be disposed on the other end of the arm.

Also, the present invention provides a method of carrying a substrate. In still other embodiments of the present invention, methods of carrying a substrate includes: a first step in which an arm is lengthily disposed perpendicular to a direction where the second chamber and the loadlock chamber are arranged; a second step in which the arm rotates to transfer a blade into the chamber; a third step in which the blade receives the substrate disposed in the loadlock chamber; a fourth step in which the blade is transferred from the loadlock chamber into the second chamber; a fifth step in which the blade transfers the substrate into the second chamber; and a sixth step in which the arm rotates so that the arm is lengthily disposed perpendicular to a direction where the second chamber and the loadlock chamber are arranged.

In some embodiments, the second and sixth steps may be performed by rotating the arm with respect to a central axis the arm, in the second step, one end of the arm, on which the blade is disposed, is disposed in the loadlock chamber, and the other end of the arm is disposed in the second chamber, and in the fourth step, the blade is transferred from the one end of the arm to the other end of the arm along the longitudinal direction of the arm.

In other embodiments, the second, fourth, and sixth steps may be performed by rotating the arm with respect to one end of the arm.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a view of a substrate treating apparatus according to an embodiment of the present invention when viewed from above;

FIG. 2 is a view of an example of the substrate treating apparatus in which loadlock chambers of FIG. 1 are stacked, and a buffer chamber is further provided so that the second chamber is stacked on the buffer chamber;

FIG. 3 is a view of a transferring unit of FIG. 1 when viewed from above;

FIG. 4 is a view of a transferring unit of FIG. 1 when viewed laterally;

FIG. 5 is a view of a blade and one end of an arm on which the blade is disposed of FIG. 3 when viewed from laterally;

FIG. 6 is a schematic view of a path through which a substrate is transferred according to a method of treating a substrate according to the present invention;

FIG. 7 is a flow chart of a method of carrying the substrate between a loadlock chamber and a second chamber according to an embodiment of the present invention;

FIGS. 8 to 12 are views for explaining the method of carrying the substrate between the loadlock chamber and the second chamber according to an embodiment of the present invention;

FIG. 13 is a view of a substrate treatment apparatus according to another embodiment of the present invention when viewed from above;

FIG. 14 is a view of a carrying unit of FIG. 13 when viewed from above;

FIG. 15 is a view of a carrying unit of FIG. 13 when viewed laterally;

FIG. 16 is a flow chart of a method of carrying a substrate between a loadlock chamber and a second chamber according to another embodiment of the present invention;

FIGS. 17 to 20 are views for explaining the method of carrying the substrate between the loadlock chamber and the second chamber according to another embodiment of the present invention; and

FIG. 21 is a view of a substrate treatment apparatus according to another embodiment of the present invention when viewed from above.

### DETAILED DESCRIPTION OF PREFERRED EMBODIMENTS

Preferred embodiments of the inventive concept will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the inventive concept to those skilled in the art. In the drawings, the thicknesses of layers and regions are exaggerated for clarity.

Hereinafter, a substrate treatment apparatus 1000 according to an embodiment of the present invention will be described.

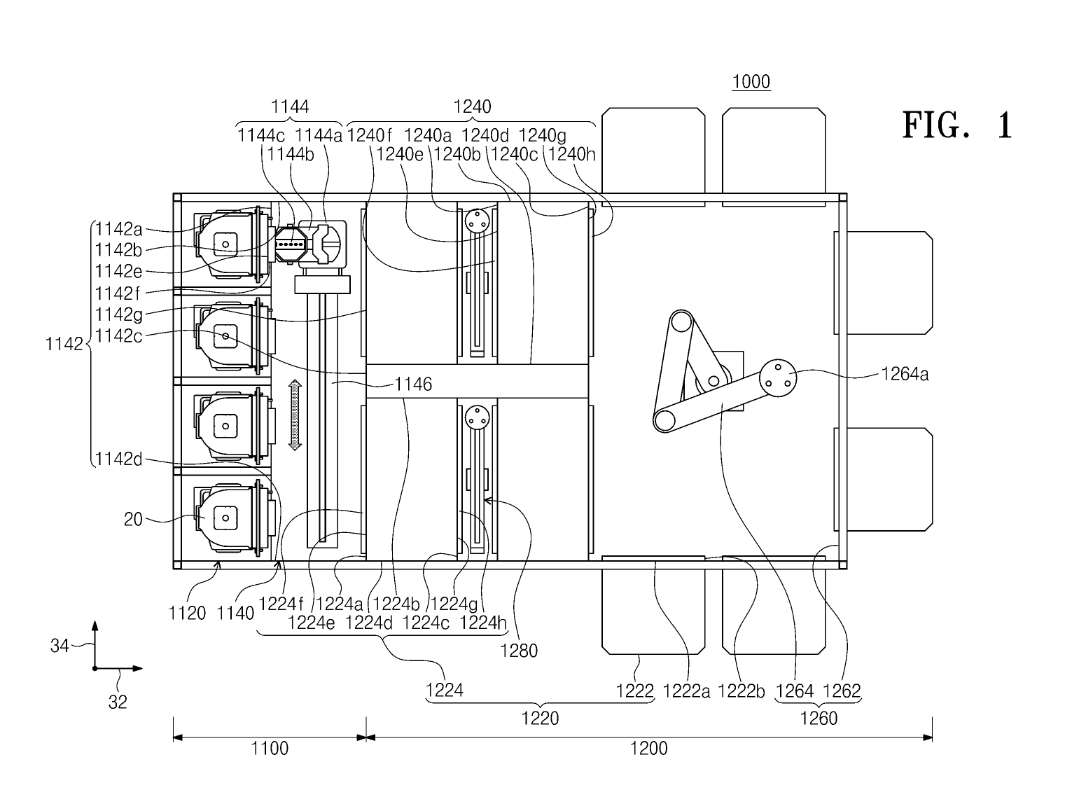

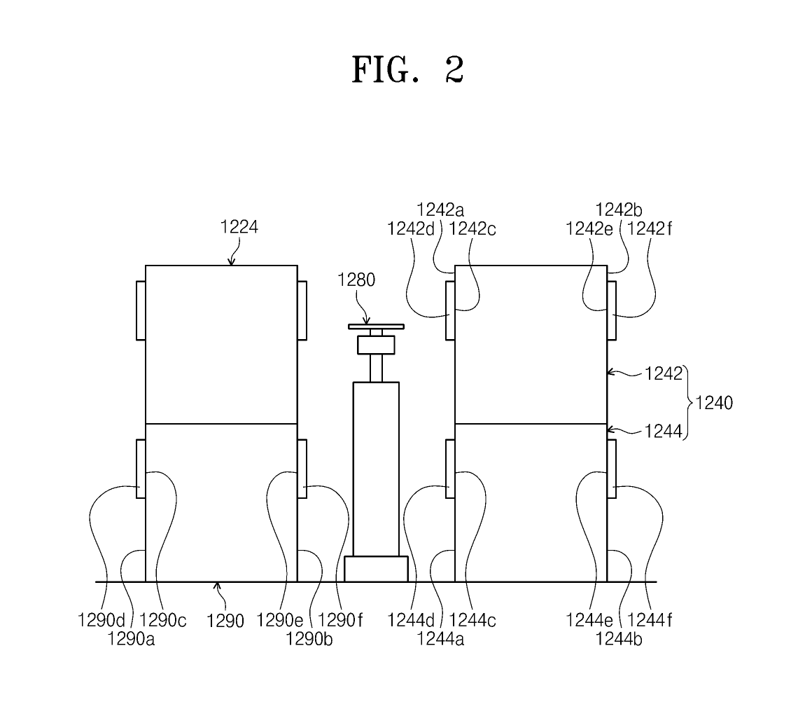

FIG. 1 is a view of a substrate treating apparatus according to an embodiment of the present invention when viewed from above. Referring to FIG. 1, the substrate treatment apparatus 1000 includes an index module 1100 and a treatment module 1200. The index module 1100 and the treatment module 1200 may be arranged in one direction. Hereinafter, a direction in which the index module 110 and the treatment module 1200 are arranged is defined as a first direction 32, and a direction perpendicular to the first direction 32 when viewed from above is defined as a second direction 34. The index module 1100 includes a load port 1120 and a frame 1140. The treatment module 1200 includes process chambers 1220 including first chambers 1222 and a second chamber 1224, a loadlock chamber 1240, a transfer chamber 1260, and a carrying unit 1280. The load port 1120, the frame 1140, the second chamber 1224, the carrying unit 1280, the loadlock chamber 1240, and the transfer chamber 1260 may be sequentially arranged in the first direction 32. The first chambers 1222 are disposed on side portions of the transfer chamber 1260, which are the side portions except a side portion where the loadlock chamber 1240 is disposed. Referring to FIG. 2, the loadlock chamber 1240 may be provided in plurality. The loadlock chamber 1240 may be stacked. The substrate treatment apparatus 1000 may further include a buffer chamber 1290 to stack the second chamber 1224 on the buffer chamber 1290. The buffer chamber 1290 may be disposed under the second chamber 1224.

Referring to FIG. 1, a container 20 in which substrates 10 are accommodated is disposed in the load port 1120. The container 20 may be loaded in or unloaded from the load port 1120 by a carrying device such as an overhead transfer. A front open unified pod (FOUP) that is an enclosed-type container may be used as the container 20. The load port 1120 may be provided in one or plurality. The load port 1120 is coupled to one side surface of the frame 1140. In FIG. 1, four load ports 1120 are disposed in the frame 1140. However, the number of the load ports 1120 may be different from the above-described number.

The frame includes a housing 1142, an index robot 1144, and a transfer rail 1146. The frame 1140 is disposed between the load port 1120 and the second chamber 1224. The housing 1142 may have a substantially rectangular parallelepiped shape. The housing 1142 includes a top surface (not shown), a bottom surface (not shown), a first side surface 1142a, a second side surface 1142b, a third side surface 1142c, and a fourth side surface 1142d. The first side surface 1142a faces the load port 1120. The third side surface 1142c faces the second chamber 1224. An entrance 1142e through which the substrate 10 is loaded or unloaded may be defined in the first side surface 1142a. The entrance 1142e may be opened and closed by a door 1142f. An entrance 1142g through which the substrate 10 is loaded or unloaded into the second chamber 1224 may be defined in the third side surface 1142c. A door opener (not shown) for opening a door (not shown) of the container 20 may be disposed in the housing 1142. A transfer rail 1146 is disposed in the housing 1142 in parallel with the second direction 34. The index robot 1144 may be mounted on the transfer rail 1143 so that the index robot 1144 linearly moves along the transfer rail 1146. The index robot 1144 includes a base 1144a, a main body 1144b, and an index arm 1144c. The base 1144a is movably disposed along the transfer rail 1146. The main body 1144b is coupled to the base 1144a. The main body 1144b may move on the base 1144a in a vertical direction. The index arm 1144c is coupled to the main body 1144b. Also, the index arm 1144c may move in forward and backward directions with respect to the main body 1144b. The index arm 1144c may be provided in plurality. The plurality of index arms 1144c may be individually operated. The index arms 1144c are stacked in a state where the index arms 1144 are vertically spaced apart from each other.

One or plurality of first chambers 1222 may be provided. An entrance 1222a through which the substrate 10 is loaded or unloaded may be defined in one side surface of the first chamber 1222. The entrance 1222a may be opened and closed by a door 1222b. The first chamber 1222 is disposed so that the one side surface in which the entrance 1222a is defined faces the inside of the transfer chamber 1260. The first chamber 1222 may perform a predetermined process with respect to the substrate 10. The first chamber 1222 may perform a process for treating the substrate 10 under a vacuum condition. For example, the first chamber 1222 may perform ashing, deposition, or etching. When the first chamber 1222 is provided in plurality, the first chambers 1222 may perform the same process or different processes with each other with respect to the substrates 10.

The second chamber 1224 is disposed between the index module 1100 and the loadlock chamber 1240. The second chamber 1224 may have a rectangular shape when viewed from above. The second chamber 1224 may have first, second, third, and fourth side surfaces 1224a, 1224b, 1224c, and 1224d that are sequentially disposed. Entrances 1224e and 1224g are defined in the first and third side surfaces 1224a and 1224c of the second chamber 1224, respectively. The entrances 1224e and 1224g may be opened and closed by doors 1224f and 1224h, respectively. The first side surface 1224a of the second chamber 1224 faces the frame 1140. The third side surface 1224c of the second chamber 1224 faces the carrying unit 1280. The second chamber 1224 may be provided in one or plurality.

The second chamber 1224 may perform a predetermined process with respect to the substrate 10. The second chamber 1224 may perform a process for treating the substrate 10 at an atmospheric pressure. For example, the second chamber 1224 may perform a cleaning process. The cleaning process may be performed with respect to the substrate 10 treated in the first chamber 1222. Liquefied chemical may be supplied to the substrate 10 to perform the cleaning process. For example, the second chamber 1224 may be provided in two. However, the number of the second chambers 1224 may be different from the above-described number.

The loadlock chamber 1240 is disposed between the carrying unit 1280 and the transfer chamber 1260. The loadlock chamber 1240 may have a rectangular shape when viewed from above. The loadlock chamber 1240 may have first, second, third, and fourth side surfaces 1240a, 1240b, 1240c, and 1240d that are sequentially disposed. Entrances 1240e and 1240g are defined in the first and third side surfaces 1240a and 1240c of the loadlock chamber 1240, respectively. The entrances 1240e and 1240g may be opened and closed by doors 1240f and 1240h, respectively. The first side surface 1240a of the loadlock chamber 1240 faces the carrying unit 1280. The third side surface 1240 of the loadlock chamber 1240 faces the transfer chamber 1260. The loadlock chamber 1240 may be provided in one or plurality. For example, two loadlock chambers 1240 may be provided. The substrate 10 transferred between the second chamber 1224 and the transfer chamber 1260 may temporarily stay in the loadlock chamber 1240. The inside of the loadlock chamber 1240 may be converted between a vacuum state and an atmospheric state. Referring to FIG. 2, when the loadlock chambers 1240 are provided in a stacking structure, an upper loadlock chamber 1242 may have first, second, third, and fourth side surfaces 1242a, (not shown), 1242b, and (not shown). Entrances 1242c and 1242e are defined in the first and third side surfaces 1242a and 1242b of the upper loadlock chamber 1242, respectively. The entrances 1242c and 1242e may be opened and closed by doors 1242d and 1242f, respectively. A lower loadlock chamber 1244 may have first, second, third, and fourth side surfaces 1244a, (not shown), 1244b, and (not shown) that are sequentially disposed. Entrances 1244c and 1244e are defined in the first and third side surfaces 1244a and 1244b of the lower loadlock chamber 1244, respectively. The entrances 1244c and 1244e may be opened and closed by doors 1244d and 1244f, respectively.

Referring to FIG. 1, the transfer chamber 1260 includes a housing 1262 and a main robot 1264. The loadlock chamber 1240 and the first chamber 1222 are disposed on the side surfaces of the transfer chamber 1260, respectively. The housing 1262 may have a polygonal shape when viewed from above. The main robot 1264 is disposed in the housing 1262. In FIG. 1, the housing 1262 has a rectangular shape when view from above. However, the housing 1262 may vary in shape thereof. The main robot 1264 is movably disposed in a vertical direction. A blade 1264a of the main robot 1264 may move forward, backward, and rotate on a horizontal plane. The blade 1264a may be provided one or plurality. The main robot 1264 carries the substrate 10 between the loadlock chamber 1240 and the first chamber 1222. In FIG. 1, the main robot 1264 has one blade 1264a. The inside of the transfer chamber 1260 may be maintained under a vacuum condition.

Referring FIG. 2, the buffer chamber 1290 may be disposed under the second chamber 1224. The buffer chamber 1290 has a square shape when viewed from above. The buffer chamber 1290 may have first, second, third, and fourth side surfaces 1290a, (not shown), 1290b, and (not shown) that are sequentially disposed. Entrances 1290c and 1290e are defined in the first and third side surfaces 1290a and 1290b of the buffer chamber 1280, respectively. The entrances 1290c and 1290e may be opened and closed by doors 1290d and 1290f, respectively. The first side surface 1290a of the buffer chamber 1290 faces the frame 1140. The third side surface 1290b of the buffer chamber 1290 faces the carrying unit 1280. The buffer chamber 1290 may be provided in one or plurality. Untreated substrate 10 may be transferred into the buffer chamber 1290 and transferred from the buffer chamber 1290 into the loadlock chamber 1244 by the carrying unit 1280.

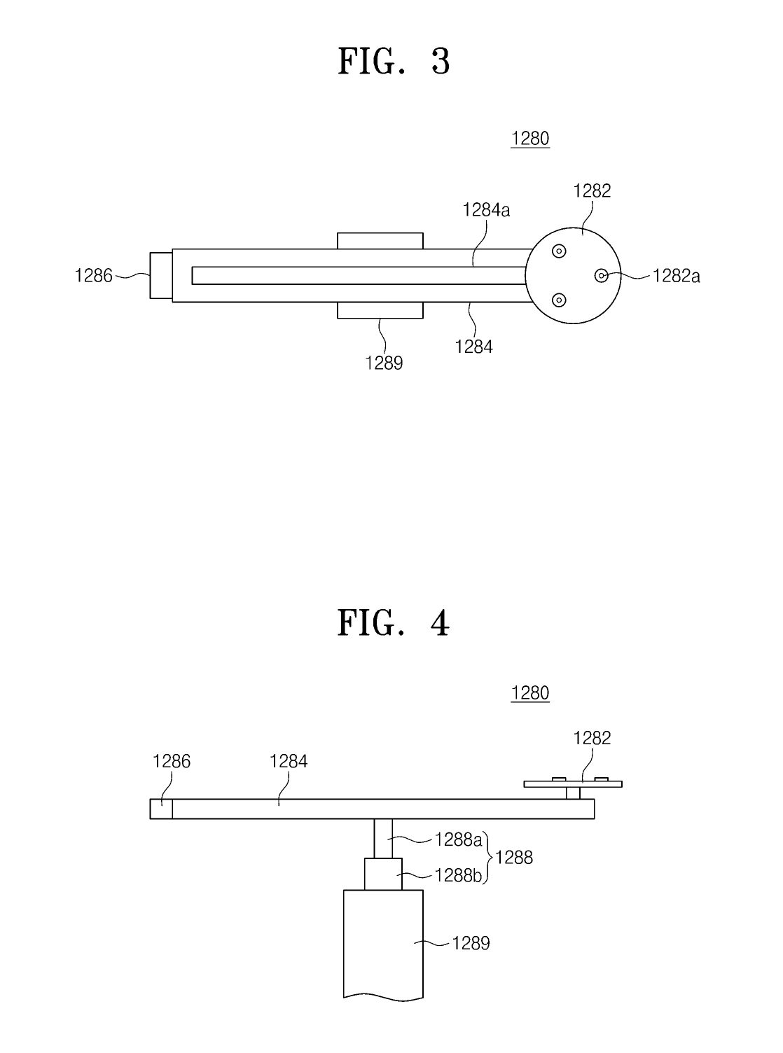

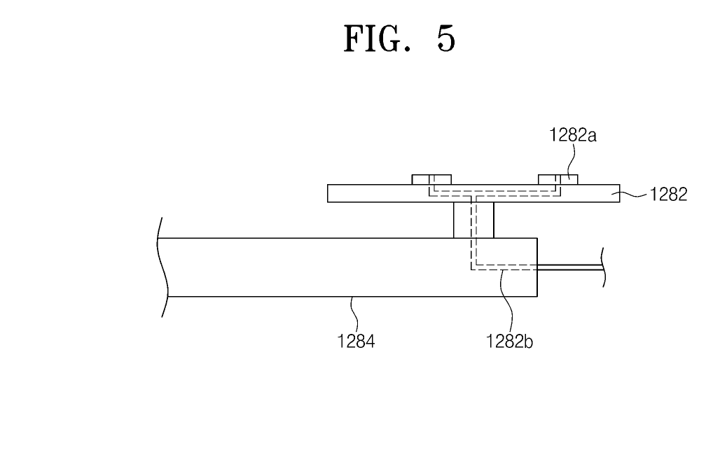

Referring to FIGS. 3 to 5, the carrying unit 1280 may include a blade 1282, an arm 1284, a blade driver 1286, a driving unit 1288, and an elevation driver 1289. The carrying unit 1280 may carry the substrate 10 between the buffer chamber 1290 and the loadlock chamber 1240 and between the second chamber 1224 and the loadlock chamber 1240. The blade 1282 disposed on a top surface of the arm 1284. A vacuum hole 1282a is defined in the blade 1282. A vacuum line 1282b is connected to the vacuum hole 1282a. A vacuum pump (not shown) is disposed in the vacuum line 1282b. The blade 1282 may support the substrate 10 in a vacuum manner. One or plurality of vacuum holes 1282a may be defined in an upper portion of the blade 1282. The arm 1284 may be lengthily disposed in parallel to the second direction 34. Also, the arm 1284 may be lengthily disposed in parallel to the first direction 32. When the arm 1284 is lengthily disposed in parallel to the first direction 32, one end of the arm 1284 may be disposed in the loadlock chamber 1242, and the other end of the arm 1284 may be disposed in the second chamber 1224. A rail 1284a may be disposed on the top surface of the arm 1284. The rail 1284a is lengthily disposed in the same direction as a longitudinal direction of the arm 1284. The rail 1284a may guide the blade 1282 to linearly move from the one end to the other end of the arm 1284. The blade driver 1286 may linearly move the blade 1282 along the longitudinal direction of the arm 1284. The driving unit 1288 includes a rotation shaft 1188a and a motor 1288b. The driving unit 1288 rotates the arm 1284 with respect to a central axis thereof. The driving unit 1288 may rotate the arm 1284 in a clockwise or counterclockwise direction. An upper end of the rotation shaft 1288a is connected to a central portion of the arm 1284. The motor 1288b is connected to a lower end of the rotation shaft 1288a. The rotation shaft 1288a transmits a driving force generated from the motor 1288b to the arm 1284. The motor 1288b generates the driving force for rotating the arm 1284. The elevation driver 1289 may be disposed under the driving unit 1288. The elevation driver 1289 moves the arm 1284 in a vertical direction. A distance between the second chamber 1224 and the loadlock chamber 1242 is shorter than a length of the arm 1284. According to the above-described structure, the substrate treatment apparatus 1000 may be reduced in footprint.

Hereinafter, a method of treating a substrate including a substrate carrying method according to the present invention will be described with reference to the above-described substrate treatment apparatus 1000.

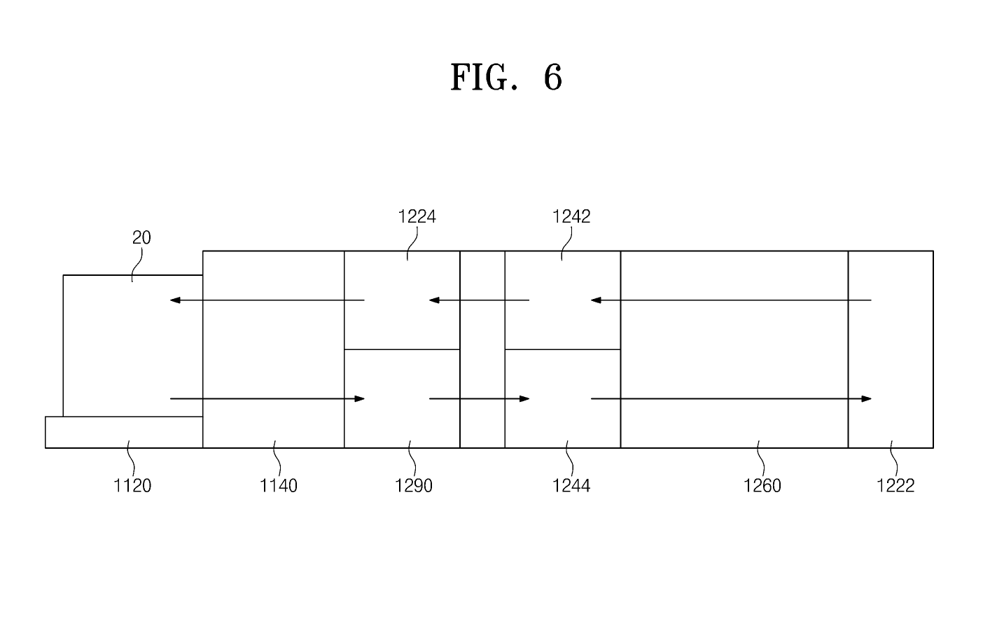

FIG. 6 is a schematic view of a path through which a substrate is transferred according to a method of treating a substrate according to the present invention. Referring to FIG. 6, At first the substrate 10 in the container 20 is transferred into the buffer chamber 1290. The substrate 10 is transferred from the buffer chamber 1290 into the lower loadlock chamber 1244. Then, the substrate is transferred from the loadlock chamber 1244 into the first chamber 1222. After the substrate 10 is treated in the first chamber 1222, the substrate 10 is transferred from the first chamber 1222 to the upper loadlock chamber 1242. The substrate is transferred from the loadlock chamber 1242 into the second chamber 1224. After the substrate 10 is treated in the second chamber 1224, the substrate 10 is transferred from the second chamber 1224 to the container 20.

Hereinafter, a process for transferring the substrate 10 from the loadlock chamber 1242 to the second chamber 1224 will be described in detail.

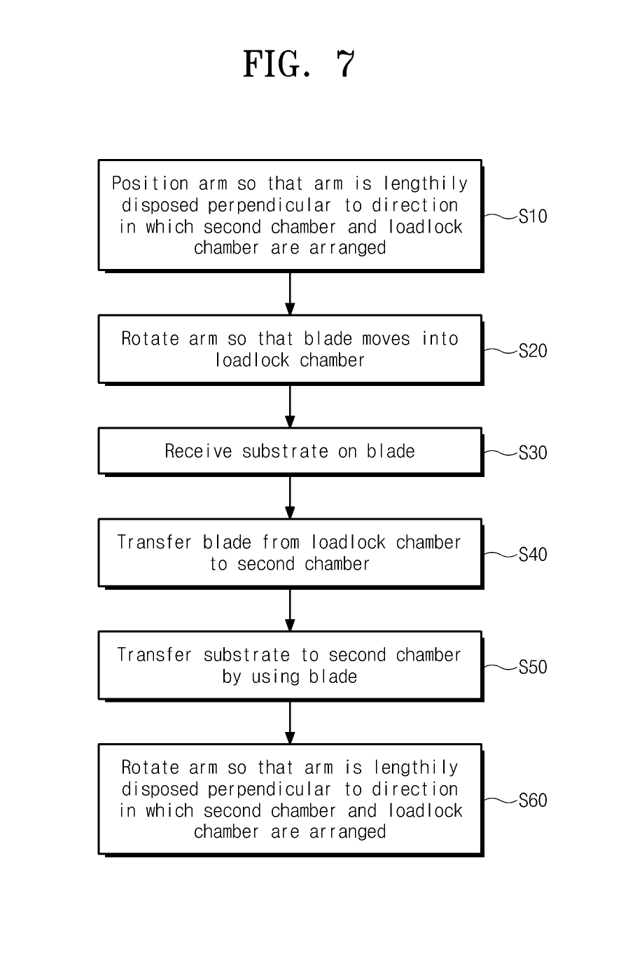

Referring to FIG. 7, the process for transferring the substrate 10 from the loadlock chamber 1242 into the second chamber 1224 includes a first process S10 to a sixth process S60.

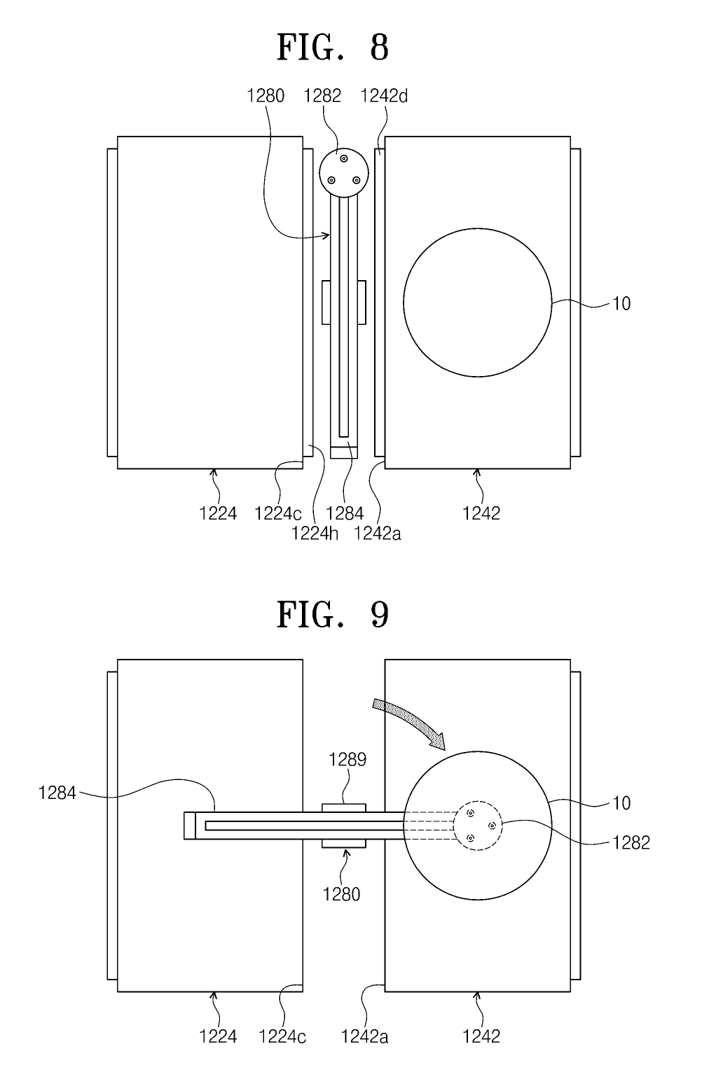

Referring to FIG. 8, in the first process S10, the arm 1284 may be lengthily disposed perpendicular to a direction in which the second chamber 1224 and the loadlock chamber 1242 are arranged. The arm 1284 is positioned at a predetermined height where the carrying unit 1280 may transfer the substrate 10 between the upper loadlock chamber 1242 and the second chamber 1224. The blade 1282 disposed on one end of the arm 1284. The door 1224h disposed on the third side surface 1224 of the second chamber 1224 and the door 1242d disposed on the first side surface 1242a of the upper loadlock chamber 1242 are closed. The inner pressure of the loadlock chamber 1242 may be adjusted.

Referring to FIG. 9, in the second process S20, the arm 1284 rotates at an angle of about 90° in a clockwise direction with respect to the central axis thereof. The blade 1282 is guided into the loadlock chamber 1242. In the second process S20, the door 1224h disposed on the third side surface 1224c of the second chamber 1224 and the door 1242d disposed on the first side surface 1242a of the loadlock chamber 1242 are opened. According to the rotation of the arm 1284, the one end of the arm 1284 on which the blade 1282 is disposed may be located at a position where the blade 1282 may receive the substrate 10 disposed in the loadlock chamber 1242, and the other end of the arm 1284 may be located in the second chamber 1224.

In a third process S30, the blade 1282 receives the substrate 10 disposed in the loadlock chamber 1242.

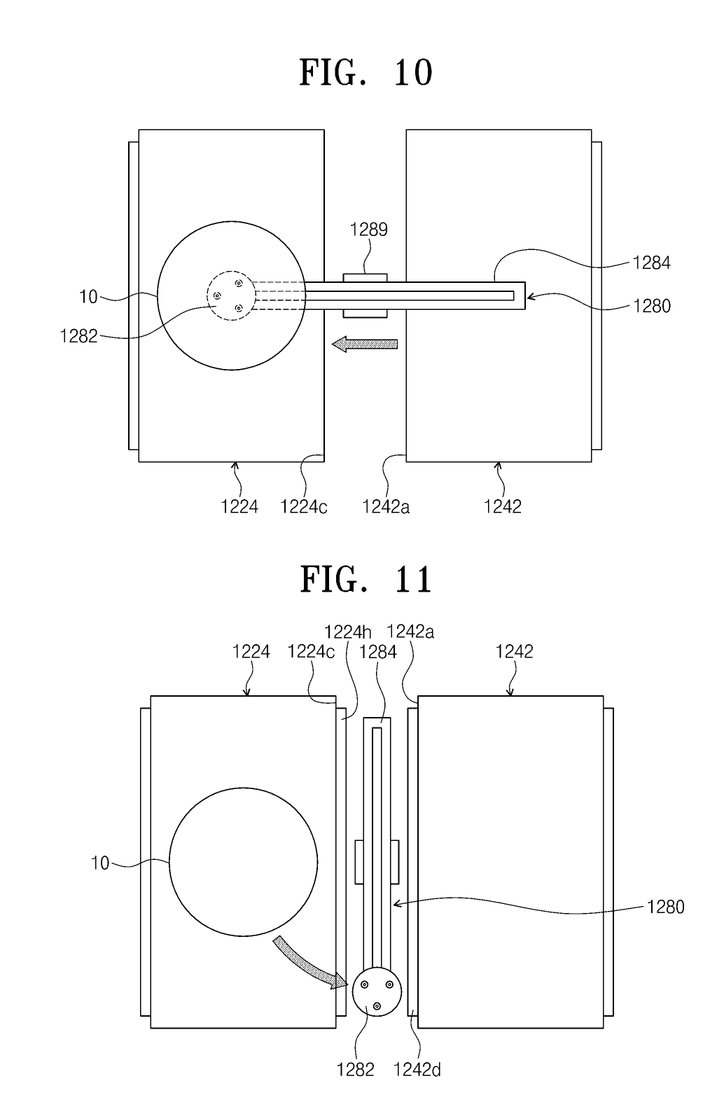

Referring to FIG. 10, in a fourth process S40, the blade 1282 is transferred from the loadlock chamber 1242 to the second chamber 1224. In the fourth process S40, in a state where the blade 1282 supports the substrate 10, the blade 1282 moves along the longitudinal direction of the arm 1284 up to a position where the blade 1282 may transfer the substrate 10 to a substrate support (not shown) in the second chamber 1224.

In a fifth process S50, the elevation driver 1289 allows the arm 1284 to descend to a height where the blade 1282 may transfer the substrate 10 to the substrate support (not shown) of the second chamber 1224. Then, the blade 1282 transfers the substrate 10 to the substrate support (not shown) of the second chamber 1224.

Referring to FIG. 11, in a sixth process S60, the arm 1284 rotates so that the arm 1284 is lengthily disposed perpendicular to a direction in which the second chamber 1224 and the loadlock chamber 1242 are arranged. In the sixth S60, the arm 1284 rotates at an angle of about 90° in a counterclockwise direction. Since the arm 1284 rotates in directions opposite to each other in the second and sixth processes S20 and S60, a twisting phenomenon in wires of the carrying unit 1280 may be prevented.

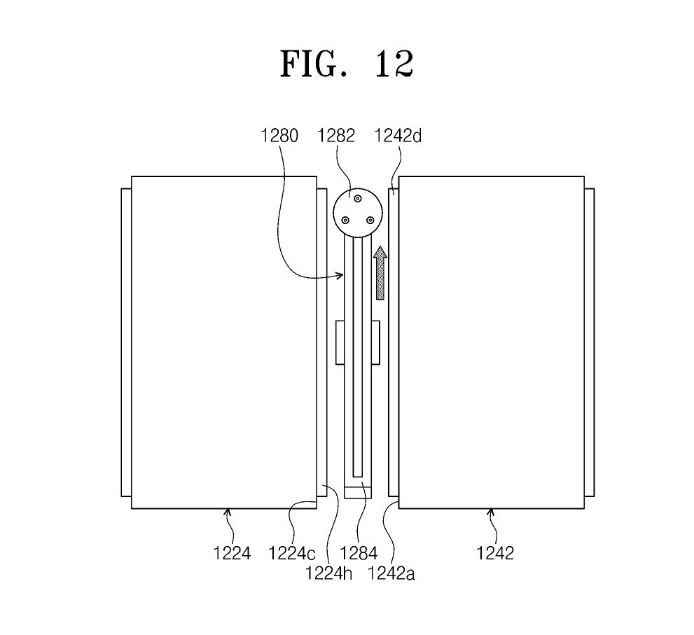

Referring to FIG. 12, after the sixth process S60, the blade 1282 is disposed on one end of the arm 1284, which faces a direction opposite to the second direction 34. Then, the blade 1282 linearly moves along the longitudinal direction of the arm 1284. Thus, the blade 1282 returns to the position where the blade 1282 is positioned in the first process S10. The door 1224h disposed on the third side surface 1224c of the second chamber 1224 and the door 1242d disposed on the first side surface 1242a of the loadlock chamber 1242 are closed.

After the sixth process S60, the blade 1282 may not be returned to the position thereof in the first process S10. In order to perform a process for transferring the substrate 10 from the buffer chamber 1290 into the lower loadlock chamber 1244, the elevation driver 1289 may allow the arm 1284 to descend to a height where the carrying unit 1280 may transfer the substrate 10 between the lower loadlock chamber 1244 and the buffer chamber 1290. In the process for transferring the substrate 10 from the buffer chamber 1290 to the lower loadlock chamber 1244, the arm 1284 may rotate in a direction opposite to that in which the arm rotates 1284 in the process for transferring the substrate 10 from the upper loadlock chamber 1242 into the second chamber 1224.

Hereinafter, a substrate treatment apparatus 2000 according to another embodiment of the present invention will be described.

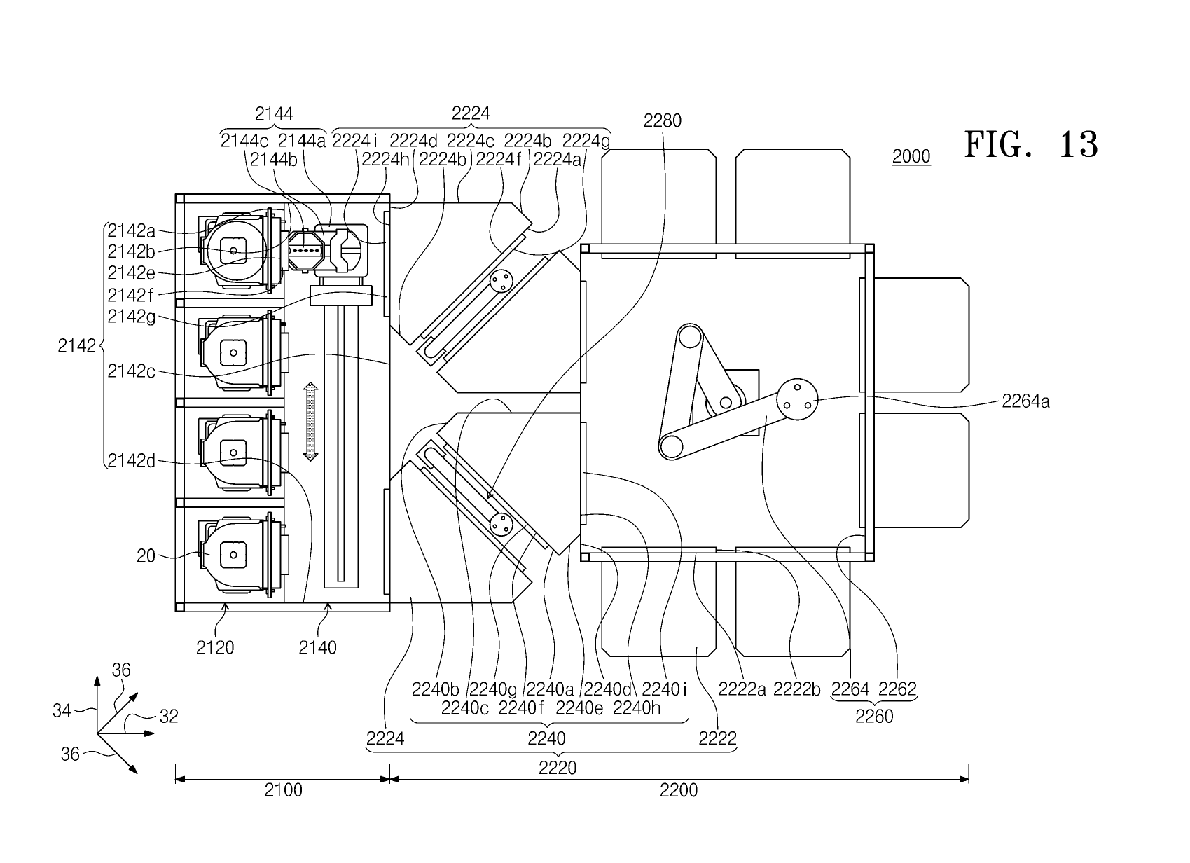

FIG. 13 is a view of a substrate treatment apparatus according to another embodiment of the present invention when viewed from above.

Referring to FIG. 13, the substrate treatment apparatus 2000 includes an index module 2100 and a treatment module 2200. The treatment module 2200 includes process chambers 2222 including a first chamber 2222 and a second chamber 2220, a loadlock chamber 2240, a transfer chamber 2260, and a carrying unit 2280. The index module 2100, the first chamber 2222, and the transfer chamber 2260 may be the same as those of the substrate treatment apparatus 1000 of FIG. 1. However, in the current embodiment, the second chamber 2224, the carrying unit 2280, and the loadlock chamber 2240 may be sequentially arranged in a third direction 36. The third direction 36 is different from the first and second directions 32 and 34. For example, an angle between the third direction 36 and the first direction 32 may be an acute angle. An angle between the third direction 36 and the first direction 32 may be about 45°. The substrate treatment apparatus 2000 may further include a buffer chamber (not shown) to stack the second chamber 2224 on the buffer chamber (not shown) like the above-described substrate treatment apparatus 1000.

The second chamber 2224 may have a pentagonal shape when viewed from above. The second chamber 2224 may have first, second, third, fourth, and fifth side surfaces 2224a, 2224b, 2224c, 2224d, and 2224e that are sequentially disposed. Entrances 2224f and 2224h through which the substrate 10 is loaded or unloaded may be defined in the first and fourth side surfaces 2224a and 2224d of the second chamber 2224, respectively. The entrances 2224f and 2224h may be opened and closed by doors 2224g and 2224i, respectively. The first side surface 2224a of the second chamber 2224 faces the carrying unit 2280. The fourth side surface 2224d of the second chamber 2224 faces the frame 2140. The second chamber 2224 may be provided in one or plurality. For example, two second chambers 2224 may be provided.

The buffer chamber (not shown) may be disposed under the second chamber 2224. The buffer chamber (not shown) may have the same shape and structure as those of the second chamber and be arranged in the same direction as that of the second chamber.

The loadlock chamber 2240 is disposed between the carrying unit 2280 and the transfer chamber 2260. The loadlock chamber 2240 may have a pentagonal shape when viewed from above. The loadlock chamber 2240 may have first, second, third, fourth, and fifth side surfaces 2240a, 2240b, 2240c, 2240d, and 2240e that are sequentially disposed. Entrances 2240e and 2240g are defined in the first and fourth side surfaces 2240a and 2240d of the loadlock chamber 2240, respectively. The entrances 1240e and 1240g may be opened and closed by doors 2240f and 2240h, respectively. The first side surface 2240a of the loadlock chamber 2240 faces the carrying unit 2280. The fourth side surface 2240d of the loadlock chamber 2240 faces the transfer chamber 2260. The loadlock chamber 2240 may be provided in one or plurality. For example, two loadlock chambers 2240 may be provided.

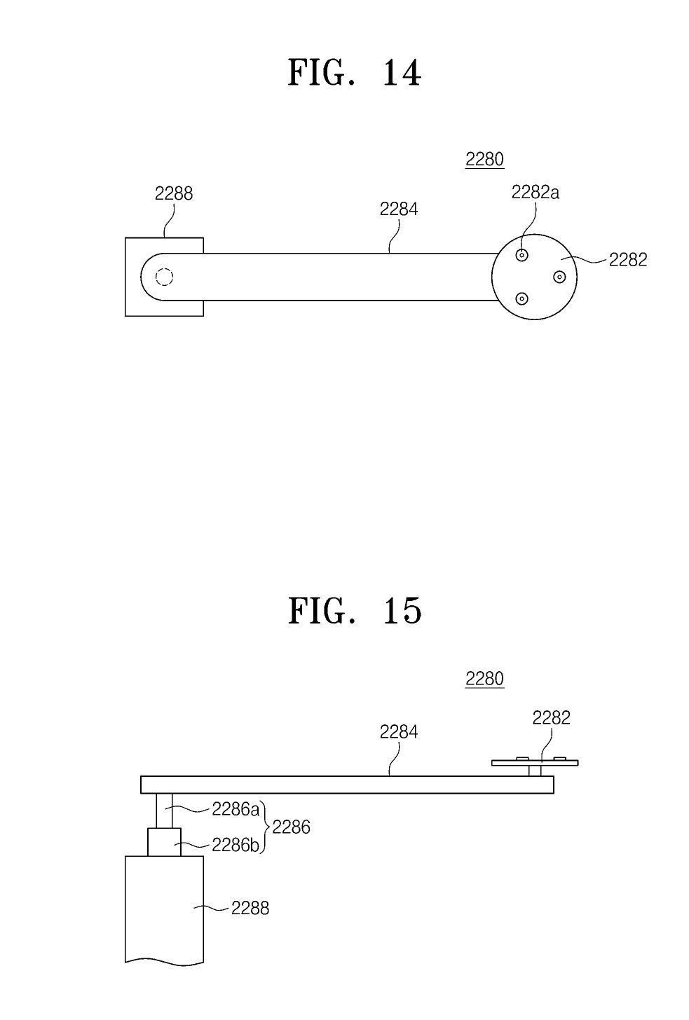

Referring to FIGS. 14 and 15, the carrying unit 2280 includes a blade 2282, an arm 2284, a driving unit 2286, and an elevation driver 2288. The blade 2282 disposed on a top surface of one end of the arm 2284. The driving unit 2286 is disposed on a bottom surface of the other end of the arm 2284.

The elevation driver 2288 is disposed under the driving unit 2286. The blade 2282 may include a vacuum hole 2282a, a vacuum line (not shown), and a vacuum pump (not shown). The blade 2282 may support the substrate 10 in a vacuum manner. The arm 2284 may be lengthily disposed in a direction in parallel to the first direction 32, a direction in parallel to the second direction 34, or a direction in parallel to the third direction 36. When the arm 2284 is lengthily disposed in a direction in parallel to the first direction 32, the one end of the arm 2284, on which the blade 2282 is disposed, may be located in the loadlock chamber 2240. When the arm 2284 is lengthily disposed in a direction in parallel to the second direction 34, the one end of the arm 2284, on which the blade 2282 is disposed, may be located in the second chamber 34. The driving unit 2286 includes a rotation shaft 2286a and a motor 2288b. The driving unit 2286 rotates the arm 2284 with respect to a central axis thereof. The driving unit 2286 may rotate the arm 2284 in a clockwise or counterclockwise direction. The rotation shaft 2286a has an upper end connected to one end of the arm 2284 and a lower end connected to the motor 2286b. The rotation shaft 2286a may transmit a driving force generated from the motor 2286b to the arm 2284. The motor 2288b may generate the driving force for rotating the arm 2284. The elevation driver 2288 moves the arm 2284 in a vertical direction. A distance between the second chamber 2224 and the loadlock chamber 2240 is shorter than a length of the arm 2284. According to the above-described structure, the substrate treatment apparatus 2000 may be reduced in footprint.

Hereinafter, another embodiment of the method for carrying the substrate of the present invention will be described with reference to the above-described substrate treatment apparatus 2000.

A substrate carrying path of the substrate treatment method may be the same as that of the above-described substrate treatment method.

Hereinafter, a process for transferring the substrate 10 from the loadlock chamber 2242 to the second chamber 2224 will be described in detail.

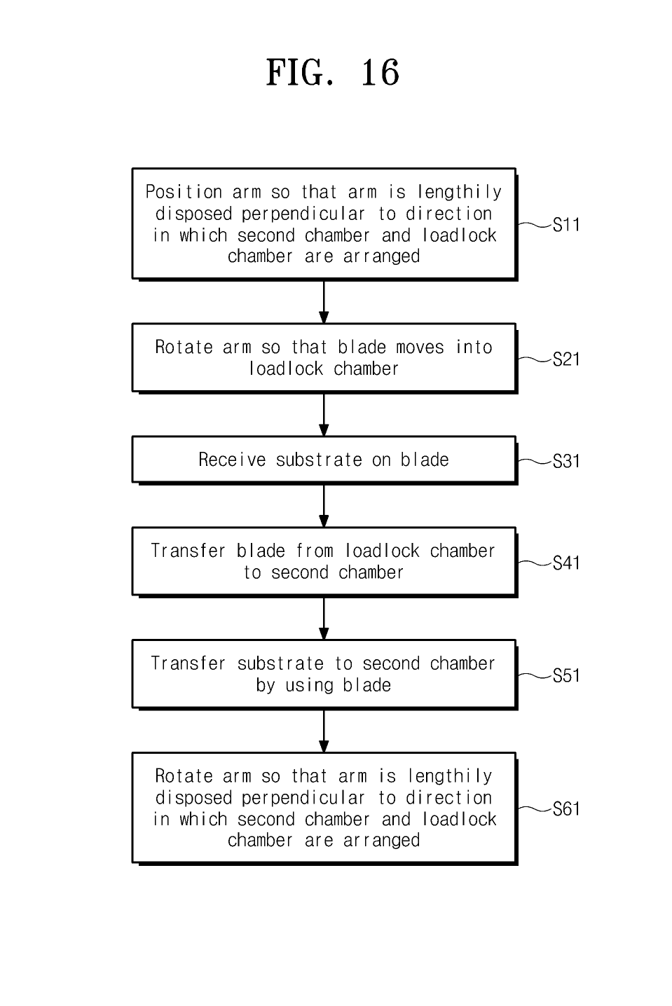

Referring to FIG. 16, the process for transferring of the substrate 10 from the loadlock chamber 2242 into the second chamber 2224 includes a first process S11 to a sixth process S61.

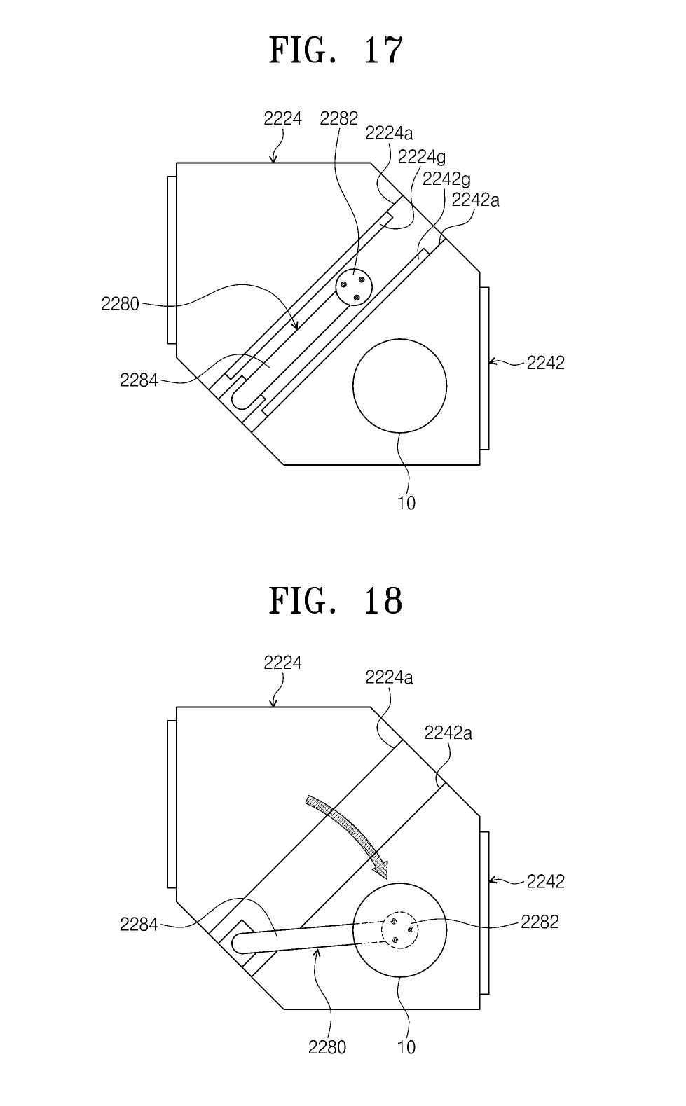

Referring to FIG. 17, in the first process S11, the arm 2284 may be lengthily disposed perpendicular to a direction in which the second chamber 2224 and the loadlock chamber 2242 are arranged. The arm 2284 is located at a height where the carrying unit 2280 may transfer the substrate 10 between the upper loadlock chamber 2242 and the second chamber 2224. The door 2224g disposed on the first side surface 2224a of the second chamber 2224 and the door 2242g disposed on the first side surface 2242a of the loadlock chamber 2242 are closed. The inner pressure of the loadlock chamber 2242 may be adjusted.

Referring to FIG. 18, in a second process S21, the arm 2284 rotates at an angle of about 45° in a clockwise direction with respect to the one end thereof. The blade 2282 is guided into the loadlock chamber 2242. In the second process S21, the door 2224g disposed on the first side surface 2224a of the second chamber 2224 and the door 2242g disposed on the first side surface 2242a of the loadlock chamber 2242 are opened. According to the rotation of the arm 2284, the one end of the arm 2282 on which the blade 2284 is disposed may be located at a position where the blade 2282 may receive the substrate 10 disposed in the loadlock chamber 2242.

In a third process S31, the blade 2282 receives the substrate 10 disposed in the loadlock chamber 2242.

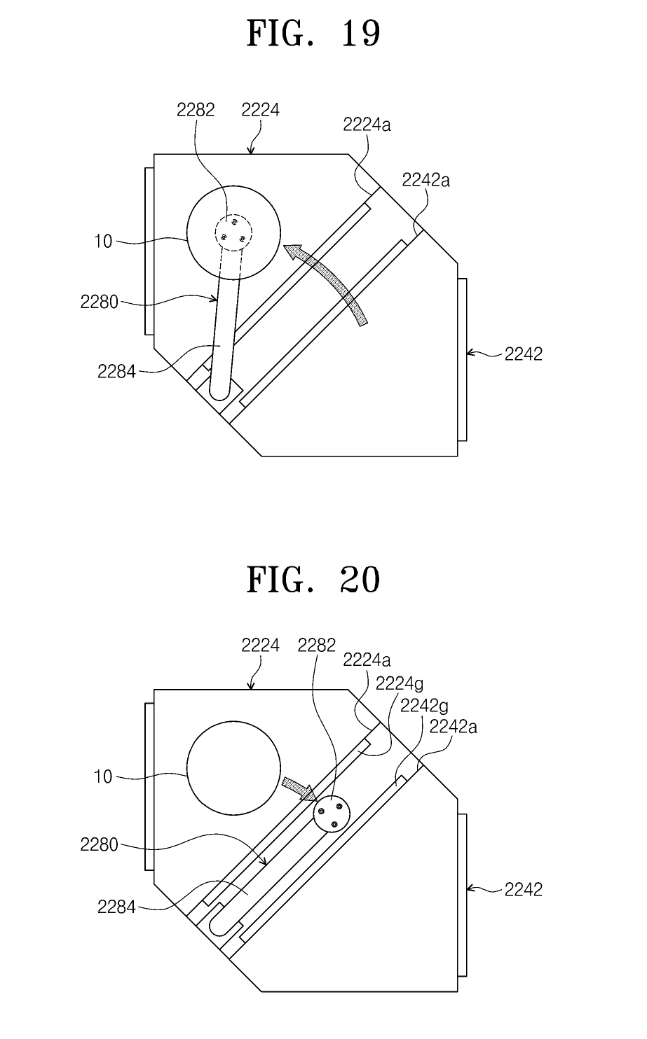

Referring to FIG. 19, in a fourth process S41, the arm 2284 rotates at an angle of about 90° in a counterclockwise direction with respect to the one end thereof. The blade 2282 is guided into the second chamber 2224. According to the rotation of the arm 2284, the one end of the arm 2282 on which the blade 2284 is disposed may be located at a position where the blade 2282 may transfer the substrate 10 to the substrate support (not shown) disposed in the second chamber 2224.

In a fifth process S51, the blade 2282 transfers the substrate 10 into the second chamber 2224. In the fifth process S51, the elevation driver 2288 allows the arm 2284 to descend to a height where the blade 2282 may transfer the substrate 10 to the substrate support (not shown) of the second chamber 2224. Then, the blade 2282 transfers the substrate 10 to the substrate support (not shown) of the second chamber 2224.

Referring to FIG. 20, in the sixth process S61, the arm 2284 rotates so that the arm 2284 is lengthily disposed perpendicular to a direction in which the second chamber 2224 and the loadlock chamber 2242 are arranged. In the sixth process S61, the arm 2284 rotates at an angle of about 45° in a clockwise direction.

The door 2224g disposed on the first side surface 2224a of the second chamber 2224 and the door 2242g disposed on the first side surface 2242a of the loadlock chamber 2242 are closed. Since the rotation direction of the arm 2284 in the second and sixth processes S21 and S61 is opposite to that of the arm 2284 in the fourth process S41, a twisting phenomenon in wires of the carrying unit 2280 may be prevented.

After the sixth process S61, in order to perform a process for transferring the substrate 10 from the buffer chamber (not shown) into the lower loadlock chamber (not shown), the elevation driver 2288 may allow the arm 2284 to descend to a height where the carrying unit 2280 may transfer the substrate 10 between the buffer chamber (not shown) and the lower loadlock chamber (not shown). In the process for transferring the substrate 10 from the buffer chamber 2284 to the lower loadlock chamber 2242, the arm 2284 rotates in a direction opposite to that in which the arm rotates 2284 in the process for transferring the substrate 10 from the upper loadlock chamber 2242 into the second chamber 2224.

The carrying unit 1280 carries the substrate 10 between the loadlock chamber 1242 and the second chamber 1224, and the carrying unit 2280 carries the substrate 10 between the loadlock chamber 2242 and the second chamber 2224 in the above embodiments. However, the present invention is not limited thereto. The carrying units 1280 and 2280 may be used to carry the substrates 10 between two units instead of the chambers.

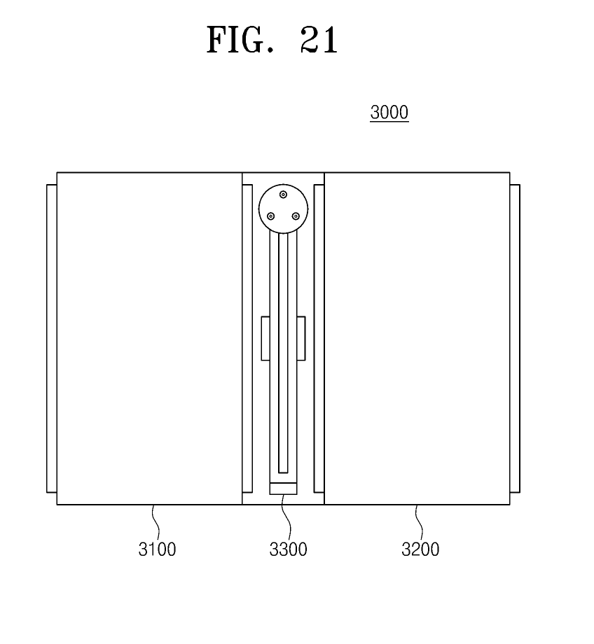

FIG. 21 is a view of a substrate treatment apparatus according to another embodiment of the present invention when viewed from above. Referring to FIG. 21, a substrate treatment apparatus 3000 according to the present invention includes a first unit 3100, a second unit 3200, and a carrying unit 3300. The carrying unit 3300 may be disposed between the first unit 3100 and the second unit 3200. The substrate treatment apparatus 3000 may be a substrate treatment apparatus for carrying the substrate 10 between the transfer chamber 1260 or 2260 and the index module 1100 or 2100 in the above substrate treatment apparatus 1000 or 2000, respectively. The first unit 3100 may be the second chamber 1224 or 2224. The second unit 3200 may be the loadlock chamber 1240 or 2240. The carrying unit 3300 is the same as the carrying unit 1280 or 2280 of the above-described substrate treatment apparatus 1000 or 2000.

The substrate treatment apparatus and the substrate carrying method according to the embodiments of the present invention may perform an atmospheric pressure process and a vacuum process in one apparatus when the substrate treatment process is performed.

Also, according to the substrate treatment apparatus and the substrate carrying method according to the embodiments of the present invention, the substrate treatment apparatus may be reduced in footprint.

If a person of ordinary skill in the art to which this invention pertains without departing from the essential characteristics of the present invention in the range described above, is only the spirit of the present invention have been described for illustrative purposes, various modifications, additions and substitutions are possible. Therefore, to explain the embodiments disclosed in the present disclosure is not limited to the technical idea of the present disclosure, and are not limited by this embodiment without departing from the scope or spirit of the invention. The scope of protection of the present disclosure, all the technical idea, within the scope of its equivalent shall be construed by the following claims should be construed as being included in the scope of the present disclosure.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. An apparatus for treating a substrate, the apparatus comprising:
an index module; and
a treatment module,
wherein the index module comprises:
a load port on which a container accommodating the substrate is placed; and
a frame in which an index robot for carrying the substrate between the container and the treatment module is disposed, and
the treatment module comprises:
process chambers comprising a first chamber and a second chamber;
a loadlock chamber;
a transfer chamber in which a main robot for transferring the substrate between the first chamber and the loadlock chamber is disposed; and
a carrying unit for carrying the substrate between the second chamber and the loadlock chamber,
wherein the carrying unit comprises:
an arm;
a blade disposed on the arm to support the substrate; and
a rotation driver for rotating the arm,
wherein the first and loadlock chambers are disposed on a side portion of the transfer chamber,
the second chamber is disposed between the loadlock chamber and the frame, and
a distance between the second chamber and the loadlock chamber is shorter than that of the arm.

2. The apparatus of claim 1, wherein the index module, the second chamber, the loadlock chamber, and the transfer chamber are arranged in a first direction.

3. The apparatus of claim 2, wherein the carrying unit further comprises a blade driver for moving the blade along a longitudinal direction of the arm on the arm.

4. The apparatus of claim 3, wherein the rotation driver rotates the arm with respect to a central axis of the arm.

5. The apparatus of claim 2, wherein each of the loadlock chamber and the second chamber has a rectangular shape when viewed from above.

6. The apparatus of claim 1, wherein the index module and the transfer chamber are arranged in a first direction, and the second chamber and the loadlock chamber are arranged in a third direction that is different from the first direction.

7. The apparatus of claim 6, wherein an angle between the first direction and the third direction is an acute angle.

8. The apparatus of claim 6, wherein an angle between the first direction and the third direction is about 45°.

9. The apparatus of claims 6, wherein the rotation driver rotates the arm with respect to one end of the arm, and the blade is disposed on the other end of the arm.

10. The apparatus of claim 6, wherein each of the loadlock chamber and the second chamber has a pentagonal shape when viewed from above.

11. The apparatus of claim 10, wherein, when viewed from above, the loadlock chamber and the second chamber are symmetrically disposed with respect to a direction perpendicular to the third direction.

12. The apparatus of claim 1, wherein the carrying unit further comprises an elevation driver moving the arm in a vertical direction,
the loadlock chamber is provided in plurality so that the plurality of loadlock chambers are stacked thereon, and
the apparatus further comprises a buffer chamber stacked under that the second chamber.

13. The apparatus of claim 1, wherein the arm is lengthily disposed perpendicular to a direction in which the second chamber and the loadlock chamber are arranged.

14. The apparatus of claim 1, wherein the first chamber is a vacuum chamber, and the second chamber is an atmospheric pressure chamber.

15. The apparatus of claim 1, wherein the first chamber is a chamber in which the substrate is treated using plasma, and the second chamber is a chamber in which the substrate is treated using a cleaning solution.

16. An apparatus for treating a substrate, the apparatus comprising:
a first unit;
a second unit;
a carrying unit disposed between the first unit and the second unit,
wherein the carrying unit comprises:
an arm;
a blade disposed on the arm to support a substrate; and
a rotation driver for rotating the arm,
wherein a distance between the first unit and the second unit is shorter than that of the arm.

17. The apparatus of claim 16, wherein the carrying unit further comprises a blade driver for moving the blade along a longitudinal direction of the arm on the arm.

18. The apparatus of claim 17, wherein the rotation driver rotates the arm with respect to a central axis of the arm.

19. The apparatus of claim 16, wherein the rotation driver rotates the arm with respect to one end of the arm, and the blade is disposed on the other end of the arm.

20. The apparatus of claim 16, wherein the arm is lengthily disposed perpendicular to a direction in which the first unit and the second unit are arranged.

21. A method of carrying a substrate between the loadlock chamber and the second chamber in the substrate treatment apparatus of claim 1, the method comprising:
a first step in which the arm is lengthily disposed perpendicular to a direction where the second chamber and the loadlock chamber are arranged;
a second step in which the arm rotates to transfer the blade into the chamber;
a third step in which the blade receives the substrate disposed in the loadlock chamber;
a fourth step in which the blade is transferred from the loadlock chamber into the second chamber;
a fifth step in which the blade transfers the substrate into the second chamber; and
a sixth step in which the arm rotates so that the arm is lengthily disposed perpendicular to a direction where the second chamber and the loadlock chamber are arranged.

22. The method of claim 21, wherein the second and sixth steps are performed by rotating the arm with respect to a central axis the arm,
in the second step, one end of the arm, on which the blade is disposed, is disposed in the loadlock chamber, and the other end of the arm is disposed in the second chamber, and
in the fourth step, the blade is transferred from the one end of the arm to the other end of the arm along the longitudinal direction of the arm.

23. The method of claim 21, wherein the rotation directions in the second and sixth steps are opposite to each other.

24. The method of claim 21, wherein the index module, the second chamber, the loadlock chamber, and the transfer chamber are arranged in a first direction.

25. The method of claim 21, wherein the second, fourth, and sixth steps are performed by rotating the arm with respect to one end of the arm.

26. The method of claim 21, wherein the index module and the transfer chamber are disposed in a first direction, and the second chamber and the loadlock chamber are arranged in a third direction that is different from the first direction.

27. The method of claim 26, wherein an angle between the first direction and the third direction is about 45°.
